(19) United States
(12) Patent Application Publication
(10) Pub. No.: US 2024/0274462 A1
(43) Pub. Date: Aug. 15, 2024

(54) SUBSTRATE PROCESSING APPARATUS AND SUBSTRATE PLACING METHOD

(71) Applicant: Tokyo Electron Limited, Tokyo (JP)

(72) Inventors: Makoto Fujiwara, Koshi City (JP); Kenji Sugakawa, Koshi City (JP); Hideyuki Fukushima, Koshi City (JP); Norifumi Kohama, Koshi City (JP); Daisuke Ikemoto, Koshi City (JP)

(21) Appl. No.: 18/441,518

(22) Filed: Feb. 14, 2024

(30) Foreign Application Priority Data
Feb. 15, 2023 (JP) 2023-021883
Nov. 17, 2023 (JP) 2023-195754

(51) Int. Cl. H01L 21/683; H01L 21/02; H01L 21/67; H01L 21/687

(52) U.S. Cl. CPC H01L 21/6838; H01L 21/02035; H01L 21/67092; H01L 21/67288; H01L 21/68714

(57) ABSTRACT

A substrate processing apparatus is equipped with a holder having, on an attraction surface configured to attract a substrate, a circular central region and an annular outer region disposed outside the central region. The substrate processing apparatus includes an attracting pressure generator configured to generate an attracting pressure in the central region and each of multiple zones separated along a circumferential direction of the outer region individually; a transforming device configured to transform the central region relative to an outer edge of the holder. A controller controls: attracting the substrate to the attraction surface, based on a bending state of the substrate, by generating the attracting pressure in at least some of the multiple zones of the outer region; and transforming, after the attracting of the substrate, the attraction surface while carrying on the attracting of the substrate.

### CROSS-REFERENCE TO RELATED APPLICATION

This application claims the benefit of Japanese Patent Application Nos. 2023-021883 and 2023-195754 filed on Feb. 15, 2023 and Nov. 17, 2023, respectively, the entire disclosures of which are incorporated herein by reference.

### TECHNICAL FIELD

The various aspects and embodiments described herein pertain generally to a substrate processing apparatus and a substrate placing method.

### BACKGROUND

Patent Document 1 discloses a bonding apparatus equipped with an upper chuck for attracting a substrate at an upper side from above and a lower chuck for attracting a substrate at a lower side from below, and configured to bond the two substrates to face each other. To bond the substrates, the bonding apparatus presses a central portion of the substrate of the upper chuck into contact with a central portion of the substrate of the lower chuck, bonds the central portions of the two substrates to each other by an intermolecular force, and expands this bonding region from the central portions to outer peripheries of the substrates.

In a substrate processing apparatus equipped with such a chuck for attracting and holding a substrate as described above, when the substrate is simply attracted, there is a likelihood that a substrate processing is performed in a state that a stress on the substrate is large due to bending of the substrate or the like.
Patent Document 1: Japanese Patent Laid-open Publication No. 2015-095579

### SUMMARY

In one exemplary embodiment, there is provided a substrate processing apparatus equipped with a holder having, on an attraction surface configured to attract a substrate, a circular central region and an annular outer region disposed outside the central region. The substrate processing apparatus includes an attracting pressure generator configured to generate an attracting pressure in the central region and each of multiple zones separated along a circumferential direction of the outer region individually; a transforming device configured to transform the central region relative to an outer edge of the holder; and a controller configured to control the attracting pressure generator and the transforming device. The controller controls: attracting the substrate to the attraction surface by operating the attracting pressure generator based on a bending state of the substrate to generate the attracting pressure in at least some of the multiple zones of the outer region; and transforming, after the attracting of the substrate, the attraction surface by operating the transforming device while carrying on the attracting of the substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a bonding apparatus according to an exemplary embodiment of the present disclosure;

FIG. 2 is a side view of the bonding apparatus of FIG. 1;

FIG. 3 is a side view illustrating an example of a first substrate and a second substrate;

FIG. 4 is a flowchart illustrating a bonding method of the bonding apparatus;

FIG. 5 is a plan view illustrating an example of a bonding module according to a first exemplary embodiment;

FIG. 6 is a side view of the bonding module of FIG. 5;

FIG. 7 is a cross sectional view illustrating an example of an upper chuck and a lower chuck;

FIG. 8 is a flowchart illustrating details of a process S109 of FIG. 4;

FIG. 9A is a side view illustrating an example of an operation in a process S112 of FIG. 8;

FIG. 9B is a side view illustrating an operation following that of FIG. 9A;

FIG. 9C is a side view illustrating an operation following that of FIG. 9B;

FIG. 10A is a cross sectional view illustrating an example of an operation in a process S113 of FIG. 8;

FIG. 10B is a cross sectional view illustrating an example of an operation in a process S114 of FIG. 8;

FIG. 10C is a cross sectional view illustrating an operation following that of FIG. 10B;

FIG. 11 is a plan view illustrating an example of an attraction surface of the lower chuck;

FIG. 12A is an explanatory diagram illustrating a lower wafer that is bent convexly;

FIG. 12B is an explanatory diagram illustrating a lower wafer that is bent concavely;

FIG. 13A is a plan view illustrating an attraction surface of the lower chuck on which the lower wafer is attracted;

FIG. 13B is a side cross sectional view illustrating a case where the attraction surface is transformed by attracting the lower wafer to the lower chuck;

FIG. 13C is a plan view illustrating a state of the lower wafer and the lower chuck after the attraction surface is transformed;

FIG. 14A is a side cross sectional view illustrating an upper wafer with no bending and a concavely bent lower wafer before they are attracted;

FIG. 14B is an explanatory diagram illustrating movements of reference points of the lower wafer before the lower wafer is attracted and after the lower chuck is transformed;

FIG. 14C is an explanatory diagram illustrating movements of the reference points of the upper wafer with slight bending and the concavely bent lower wafer before they are attracted and movement of the reference points of the lower wafer after the lower chuck is transformed;

FIG. 15A is a side cross sectional view illustrating a convexly bent upper wafer and a lower wafer with no bending before they are attracted;

FIG. 15B is an explanatory diagram illustrating movements of reference points of the upper wafer before the upper wafer is attracted and movements of the reference points of the lower wafer after the lower chuck is transformed;

FIG. 15C is an explanatory diagram illustrating movements of the reference points of the convexly bent upper wafer and the lower wafer with slight bending before they are attracted and movement of the reference points of the lower wafer after the lower chuck is transformed;

FIG. 16 is a flowchart illustrating a bonding method including a substrate placing method;

FIG. 17A is a plan view illustrating an attraction pattern according to a first modification example;

FIG. 17B is a plan view illustrating an attraction pattern according to a second modification example;

FIG. 17C is a plan view illustrating an attraction pattern according to a third modification example;

FIG. 17D is a plan view illustrating an attraction pattern according to a fourth modification example;

FIG. 17E is a plan view illustrating an attraction pattern according to a fifth modification example;

FIG. 17F is a plan view illustrating an attraction pattern according to a sixth modification example;

FIG. 18A is a first side view schematically illustrating deformation of a lower wafer according to another exemplary embodiment;

FIG. 18B is a second side view schematically illustrating deformation of the lower wafer according to the another exemplary embodiment;

FIG. 18C is a first plan view illustrating an attraction surface configured to attract the lower wafer according to the another exemplary embodiment;

FIG. 18D is a second plan view illustrating the attraction surface configured to attract the lower wafer according to the another exemplary embodiment; and

FIG. 19 is a flowchart illustrating a bonding method including a substrate placing method according to the another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, like parts will be assigned like reference numerals, and redundant description will be omitted.

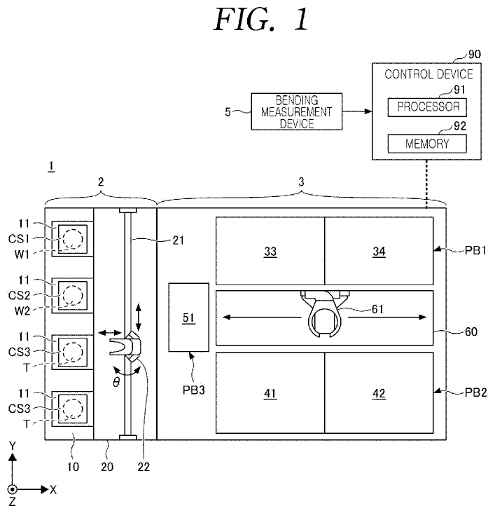

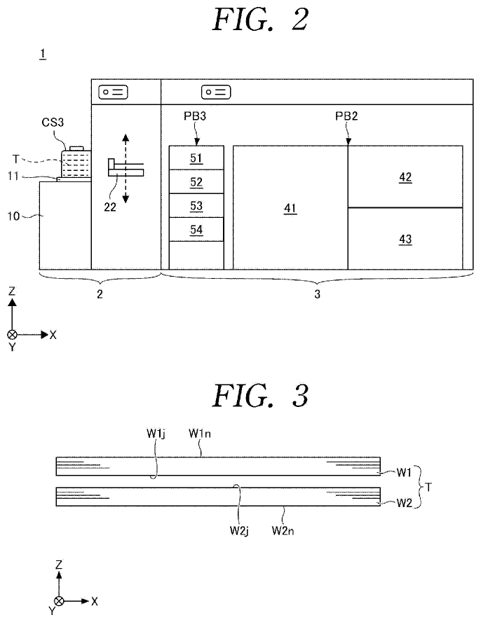

As a substrate processing apparatus according to the present disclosure, a bonding apparatus 1 shown in FIG. 1 and FIG. 2 will be described representatively. Here, however, it should be noted that the substrate processing apparatus of the present disclosure is not limited to the bonding apparatus 1 and may be any of various other apparatuses including a holder configured to hold a substrate and process the substrate held by the holder. Examples of other substrate processing apparatuses include an exposure apparatus, a temperature control apparatus, and so forth. The exposure apparatus is an apparatus configured to hold a substrate with a holder and transfer a mask pattern onto the substrate. The temperature control apparatus is an apparatus configured to hold a substrate with a holder and control a temperature of the substrate.

The bonding apparatus 1 is configured to produce a bonded substrate T by bonding a first substrate W1 and a second substrate W2, as shown in FIG. 3. At least one of the first substrate W1 and the second substrate W2 is a substrate on which a plurality of electronic circuits are formed on a semiconductor substrate such as, but not limited to, a silicon wafer or a compound semiconductor wafer. One of the first substrate W1 and the second substrate W2 may be a bare wafer on which no electronic circuit is formed. Although not particularly limited, the compound semiconductor wafer may be, for example, a GaAs wafer, a SiC wafer, a GaN wafer, or an InP wafer.

The first substrate W1 and the second substrate W2 are formed on circular plates having substantially the same shape (same diameter). The bonding apparatus 1 places the second substrate W2 on the negative Z-axis side of (vertically under) the first substrate W1, and bonds the first substrate W1 and the second substrate W2. Hereinafter, the first substrate W1 as one of the substrates may sometimes be referred to as “upper wafer W1”; the second substrate W2 as the other of the substrates, “lower wafer W2”; and the bonded substrate T, “bonded wafer T”. In addition, hereinafter, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As depicted in FIG. 1, the bonding apparatus 1 is equipped with a carry-in/out station 2 and a processing station 3 which are arranged in this order along the positive X-axis direction. The carry-in/out station 2 and the processing station 3 are connected as one body.

The carry-in/out station 2 includes a placing table 10 and a transfer section 20. The placing table 10 is equipped with a multiple number of placing plates 11. Provided on the placing plates 11 are cassettes CS1, CS2 and CS3 each of which accommodates therein a plurality of (e.g., 25 sheets of) substrates horizontally. The cassette CS1 accommodates therein upper wafers W1; the cassette CS2, lower wafers W2; and the cassettes CS3, bonded wafers T. Further, the upper wafers W1 and the lower wafers W2 are accommodated in the cassette CS1 and the cassette CS2, respectively, with the bonding surfaces W1j and W2j facing upwards while being aligned in the same direction.

The transfer section 20 is provided adjacent to the positive X-axis side of the placing table 10, and is equipped with a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis, and serves to transfer the upper wafers W1, the lower wafers W2, and the bonded wafers T between the cassettes CS1 to CS3 placed on the placing table 10 and a third processing block PB3 of the processing station 3 to be described later.

The processing station 3 has, for example, three processing blocks PB1, PB2, and PB3. The first processing block PB1 is provided on the rear side (positive Y-axis side of FIG. 1) of the processing station 3. The second processing block PB2 is provided on the front side (negative Y-axis side of FIG. 1) of the processing station 3. The third processing block PB3 is provided on the carry-in/out station 2 side (negative X-axis side of FIG. 1) of the processing station 3.

Further, the processing station 3 is equipped with a transfer section 60 having a transfer device 61 in a region surrounded by the first processing block PB1 to the third processing block PB3. For example, the transfer device 61 has a transfer arm configured to be movable in a vertical direction and a horizontal direction and pivotable around a vertical axis. The transfer device 61 is moved within the transfer section 60 to transfer the upper wafers W1, the lower wafers W2, and the bonded wafers T to devices within the first processing block PB1, the second processing block PB2, and the third processing block PB3 which are adjacent to the transfer section 60.

The first processing block PB1 includes, for example, a surface modifying apparatus 33 and a surface hydrophilizing apparatus 34. The surface modifying apparatus 33 is configured to modify the bonding surface W1j of the upper wafer W1 and the bonding surface W2j of the lower wafer W2. The surface hydrophilizing apparatus 34 is configured to hydrophilize the modified bonding surfaces W1j and W2j of the upper and lower wafers W1 and W2, respectively.

By way of example, the surface modifying apparatus 33 cuts a SiO₂ bond on the bonding surfaces W1j and W2j to form a dangling bond of Si, thus allowing the bonding surfaces W1j and W2j to be hydrophilized afterwards. In the surface modifying apparatus 33, an oxygen gas as a processing gas is excited into plasma to be ionized under a decompressed atmosphere, for example. As oxygen ions are radiated to the bonding surface W1j of the upper wafer W1 and the bonding surface W2j of the lower wafer W2, the bonding surfaces W1j and W2j are plasma-processed to be modified. The processing gas is not limited to the oxygen gas, but it may be a nitrogen gas or the like.

The surface hydrophilizing apparatus 34 is configured to hydrophilize the bonding surface W1j of the upper wafer W1 and the bonding surface W2j of the lower wafer W2 with a hydrophilizing liquid such as pure water. The surface hydrophilizing apparatus 34 also has a function of cleaning the bonding surfaces W1j and W2j. In this surface hydrophilizing apparatus 34, while rotating the upper wafer W1 or the lower wafer W2 held by, for example, a spin chuck, the pure water is supplied onto the upper wafer W1 or the lower wafer W2. Accordingly, the pure water is diffused on the bonding surfaces W1j and W2j, and an OH group is attached to the dangling bond of Si, so that the bonding surfaces W1j and W2j are hydrophilized.

As shown in FIG. 2, the second processing block PB2 includes, for example, a bonding module 41, a first temperature control device 42, and a second temperature control device 43. The bonding module 41 is configured to bond the hydrophilized upper wafer W1 and lower wafer W2 to produce the bonded wafer T. The first temperature control device 42 is configured to adjust a temperature distribution of the upper wafer W1 before producing the bonded wafer T. The second temperature control device 43 is configured to adjust a temperature distribution of the lower wafer W2 before producing the bonded wafer T. In addition, in the present exemplary embodiment, although the first temperature control device 42 and the second temperature control device 43 are provided separately from the bonding module 41, they may be provided as a part of the bonding module 41.

The third processing block PB3 is equipped with a first position adjusting device 51, a second position adjusting device 52, and transition devices 53 and 54 in this order from top to bottom, for example. Further, the places where the individual devices are disposed in the third processing block PB3 are not limited to the example shown in FIG. 2. The first position adjusting device 51 is configured to adjust a direction of the upper wafer W1 in a horizontal direction, and invert the upper wafer W1 upside down so that the bonding surface W1j of the upper wafer W1 faces downwards. The second position adjusting device 52 is configured to adjust a direction of the lower wafer W2 in a horizontal direction. The transition device 53 is configured to temporarily place therein the upper wafer W1. Further, the transition device 54 is configured to temporarily place therein the lower wafer W2 and the bonded wafer T.

Referring back to FIG. 1, the bonding apparatus 1 is equipped with a control device (controller) 90 configured to control the individual constituent components. The control device 90 is a control computer having one or more processors 91, a memory 92, a non-illustrated input/output interface, and an electronic circuit. The one or more processors 91 are implemented by one of a CPU (Central Processing Unit), a GPU (Graphics Processing Unit), an ASIC (Application Specific Integrated Circuit), an FPGA (Field-Programmable Gate Array), and a circuit composed of a plurality of discrete semiconductors, or a combination thereof. The memory 92 includes a main storage device composed of a semiconductor memory or the like; and an auxiliary storage device made of a disk, a drive, a semiconductor memory, or the like. The processor 91 executes and processes a program stored in the memory 92.

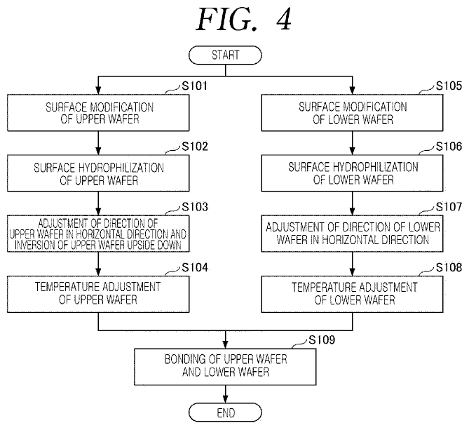

Now, referring to FIG. 4, a bonding method of the present exemplary embodiment will be explained. Processes S101 to S109 shown in FIG. 4 are performed under the control of the control device 90.

In the bonding method, an operator or a transfer robot (not shown) places the cassette CS1 accommodating therein the plurality of upper wafers W1, the cassette CS2 accommodating therein the plurality of lower wafers W2, and the empty cassette CS3 on the placing table 10 of the carry-in/out station 2.

The bonding apparatus 1 takes out the upper wafer W1 in the cassette CS1 by the transfer device 22, and transfers it to the transition device 53 of the third processing block PB3 of the processing station 3. Thereafter, the bonding apparatus 1 takes out the upper wafer W1 from the transition device 53 by the transfer device 61, and transfers it to the surface modifying apparatus 33 of the first processing block PB1.

Next, the bonding apparatus 1 modifies the bonding surface W1j of the upper wafer W1 by the surface modifying apparatus 33 (process S101). The surface modifying apparatus 33 modifies the bonding surface W1j in the state that the bonding surface W1j faces upwards. Then, the transfer device 61 takes out the upper wafer W1 from the surface modifying apparatus 33, and transfers it to the surface hydrophilizing apparatus 34.

Then, the bonding apparatus 1 hydrophilizes the bonding surface W1j of the upper wafer W1 by the surface hydrophilizing apparatus 34 (process S102). The surface hydrophilizing apparatus 34 hydrophilizes the bonding surface W1j in the state that the bonding surface W1j faces upwards. Thereafter, the transfer device 61 takes out the upper wafer W1 from the surface hydrophilizing apparatus 34, and transfers it to the first position adjusting device 51 of the third processing block PB3.

The bonding apparatus 1 adjusts the direction of the upper wafer W1 in the horizontal direction and inverts the upper wafer W1 upside down by the first position adjusting device 51 (process S103). As a result, a notch of the upper wafer W1 is directed in a predetermined direction, and the bonding surface W1j of the upper wafer W1 is turned to face downwards. Thereafter, the transfer device 61 takes out the upper wafer W1 from the first position adjusting device 51, and transfers it to the first temperature control device 42 of the second processing block PB2.

The bonding apparatus 1 adjusts the temperature of the upper wafer W1 by the first temperature control device 42 (process S104). The temperature adjustment of the upper wafer W1 is performed with the bonding surface W1j of the upper wafer W1 facing downwards. Thereafter, the transfer device 61 takes out the upper wafer W1 from the first temperature control device 42, and transfers it to the bonding module 41.

The bonding apparatus 1 performs a processing on the lower wafer W2 in parallel with the above-described processing on the upper wafer W1. First, the bonding apparatus 1 takes out the lower wafer W2 in the cassette CS2 by the transfer device 22, and transfers it to the transition device 54 of the third processing block PB3 of the processing station 3. Then, the transfer device 61 takes out the lower wafer W2 from the transition device 54, and transfers it to the surface modifying apparatus 33 of the first processing block PB1.

The bonding apparatus 1 modifies the bonding surface W2j of the lower wafer W2 by the surface modifying apparatus 33 (process S105). The surface modifying apparatus 33 modifies the bonding surface W2j in the state that the bonding surface W2j faces upwards. Thereafter, the transfer device 61 takes out the lower wafer W2 from the surface modifying apparatus 33, and transfers it to the surface hydrophilizing apparatus 34.

The bonding apparatus 1 hydrophilizes the bonding surface W2j of the lower wafer W2 by the surface hydrophilizing apparatus 34 (process S106). The surface hydrophilizing apparatus 34 hydrophilizes the bonding surface W2j in the state that the bonding surface W2j faces upwards. Then, the transfer device 61 takes out the lower wafer W2 from the surface hydrophilizing apparatus 34, and transfers it to the second position adjusting device 52 of the third processing block PB3.

The bonding apparatus 1 adjusts the direction of the lower wafer W2 in the horizontal direction by the second position adjusting device 52 (process S107). As a result, a notch of the lower wafer W2 is directed toward a predetermined direction. Thereafter, the transfer device 61 takes out the lower wafer W2 from the second position adjusting device 52, and transfers it to the second temperature control device 43 of the second processing block PB2.

The bonding apparatus 1 adjusts the temperature of the lower wafer W2 by the second temperature control device 43 (process S108). The temperature adjustment of the lower wafer W2 is performed with the bonding surface W2j of the lower wafer W2 facing upwards. Thereafter, the transfer device 61 takes out the lower wafer W2 from the second temperature control device 43, and transfers it to the bonding module 41.

Then, the bonding apparatus 1 bonds the upper wafer W1 and the lower wafer W2 in the bonding module 41 to produce the bonded wafer T (process S109). After the production of the bonded wafer T, the transfer device 61 takes out the bonded wafer T from the bonding module 41, and transfers it to the transition device 54 of the third processing block PB3.

Finally, the bonding apparatus 1 takes out the bonded wafer T from the transition device 54 by the transfer device 22, and transfers it to the cassette CS3 on the placing table 10. Thus, the series of processes are ended.

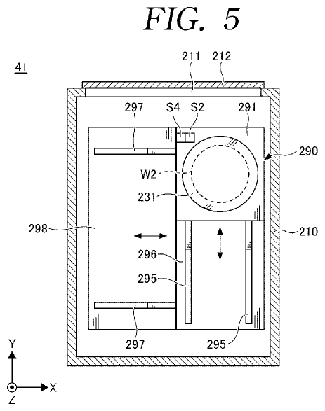

Now, with reference to FIG. 5 to FIG. 7, an example of the bonding module 41 according to the present exemplary embodiment will be described. As depicted in FIG. 5, the bonding module 41 is equipped with a processing vessel 210 having a sealable inside. A carry-in/out opening 211 is formed on a side surface of the processing vessel 210 on the transfer section 60 side, and an opening/closing shutter 212 is provided at the carry-in/out opening 211. The upper wafer W1, the lower wafer W2, and the bonded wafer T are carried in and out through the carry-in/out opening 211.

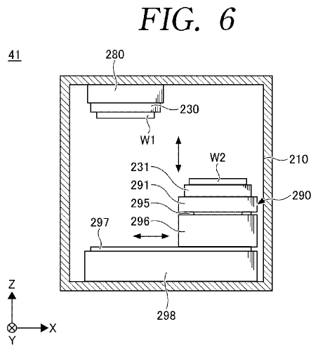

As shown in FIG. 6, an upper chuck (upper holder) 230 and a lower chuck (holder) are provided inside the processing vessel 210. The upper chuck 230 holds the upper wafer W1 from above while allowing the bonding surface W1j of the upper wafer W1 to face downwards. Further, the lower chuck 231 is disposed below the upper chuck 230, and holds the lower wafer W2 from below while allowing the bonding surface W2j of the lower wafer W2 to face upwards.

The upper chuck 230 is supported by a supporting member 280 provided on a ceiling surface of the processing vessel 210. Meanwhile, the lower chuck 231 is supported by a first lower chuck mover 291 provided below the lower chuck 231.

The first lower chuck mover 291 moves the lower chuck 231 in a horizontal direction (Y-axis direction) as will be described later. Further, the first lower chuck mover 291 is configured to be capable of moving the lower chuck 231 in a vertical direction and rotating it around a vertical axis.

The first lower chuck mover 291 is mounted to a pair of rails 295 provided on a bottom surface side of the first lower chuck mover 291 and extending in the horizontal direction (Y-axis direction). The first lower chuck mover 291 is configured to be movable along the rails 295. The rails 295 are provided on the second lower chuck mover 296.

The second lower chuck mover 296 is mounted to a pair of rails 297 provided on a bottom surface side of the second lower chuck mover 296 and extending in a horizontal direction (X-axis direction). The second lower chuck mover 296 is configured to be movable along the rails 297. In addition, the pair of rails 297 are disposed on a placing table 298 which is provided on a bottom surface of the processing vessel 210.

The first lower chuck mover 291 and the second lower chuck mover 296 constitute a moving mechanism 290. The moving mechanism 290 moves the lower chuck 231 relative to the upper chuck 230. Further, the moving mechanism 290 moves the lower chuck 231 between a substrate delivery position and a bonding position.

The substrate delivery position is a position where the upper chuck 230 receives the upper wafer W1 from the transfer device 61, the lower chuck 231 receives the lower wafer W2 from the transfer device 61, and the lower chuck 231 delivers the bonded wafer T to the transfer device 61. The substrate delivery position is a position where a carry-out of the bonded wafer T produced by the n^{th} (n is a natural number equal to or larger than 1) bonding and a carry-in of the upper wafer W1 and the lower wafer W2 to be bonded by the (n+1)^{th} bonding are performed in succession. The substrate delivery position is, for example, a position shown in FIG. 5 and FIG. 6.

When handing the upper wafer W1 over to the upper chuck 230, the transfer device 61 advances to a space directly below the upper chuck 230. Further, when receiving the bonded wafer T from the lower chuck 231 and handing the lower wafer W2 over to the lower chuck 231, the transfer device 61 advances to a space directly above the lower chuck 231. The upper chuck 230 and the lower chuck 231 are placed sideways apart, and a distance between the upper chuck 230 and the lower chuck 231 in a vertical direction is large so that the transfer device 61 advances therebetween easily.

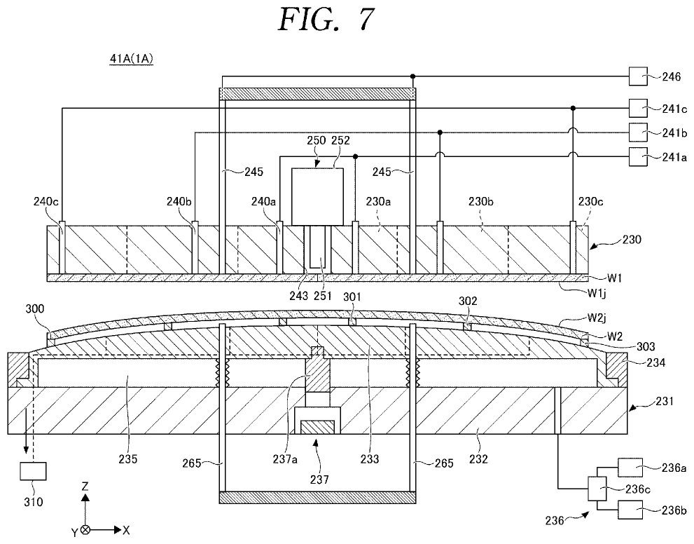

Meanwhile, the bonding position is a position (facing position) where the upper wafer W1 and the lower wafer W2 are made to face each other at a preset distance therebetween. The bonding position is, for example, a position shown in FIG. 7. At the bonding position, the distance between the upper wafer W1 and the lower wafer W2 in the vertical direction is narrower than that at the substrate delivery position. Further, at the bonding position, the upper wafer W1 and the lower wafer W2 overlap each other when viewed from the vertical direction, unlike at the substrate delivery position.

The moving mechanism 290 moves the relative positions of the upper chuck 230 and the lower chuck 231 in horizontal directions (both the X-axis direction and the Y-axis direction) and a vertical direction. Although the moving mechanism 290 moves the lower chuck 231 in the present exemplary embodiment, it may move any one of the lower chuck 231 and the upper chuck 230, or both of them. Further, the moving mechanism 290 may rotate the upper chuck 230 or the lower chuck 231 around a vertical axis.

As illustrated in FIG. 7, the upper chuck 230 is divided into a plurality of (for example, three) regions 230a, 230b, and 230c along a radial direction of the upper chuck 230. These regions 230a, 230b, and 230c are provided in this order from a center of the upper chuck 230 toward an outer periphery thereof. The region 230a is formed in a circular shape when viewed from the top, and the regions 230b and 230c are formed in an annular shape when viewed from the top.

Suction lines 240a, 240b, and 240c are independently provided in the regions 230a, 230b, and 230c, respectively. Different vacuum pumps 241a, 241b, and 241c are connected to the suction lines 240a, 240b, and 240c, respectively. The upper chuck 230 is capable of vacuum-attracting the upper wafer W1 in each of the regions 230a, 230b, and 230c individually.

The upper chuck 230 is provided with a multiple number of holding pins 245 configured to be movable up and down in a vertical direction. The plurality of holding pins 245 are connected to a vacuum pump 246, and the upper wafer W1 is vacuum-attracted to the holding pins 245 by the operation of the vacuum pump 246. The upper wafer W1 is vacuum-attracted to lower ends of the plurality of holding pins 245. Instead of the plurality of holding pins 245, a ring-shaped attraction pad may be used.

The plurality of holding pins 245 are protruded from an attraction surface of the upper chuck 230 as they are lowered by a non-illustrated driving unit. In this state, the plurality of holding pins 245 receives the upper wafer W1 from the transfer device 61 by vacuum-attracting it. Thereafter, the plurality of holding pins 245 are raised, allowing the upper wafer W1 to come into contact with the attraction surface of the upper chuck 230. Then, the upper chuck 230 vacuum-attracts the upper wafer W1 horizontally in the respective regions 230a, 230b, and 230c by the operations of the vacuum pumps 241a, 241b, and 241c, respectively.

In addition, the upper chuck 230 has, at the center thereof, a through hole 243 formed through the upper chuck 230 in a vertical direction, and is equipped with a pushing member 250 near the through hole 243. The pushing member 250 presses the center of the upper wafer W1 spaced apart from the lower wafer W2, thus bringing the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driver (not shown) having a motor therein, and is protruded from the attraction surface of the upper chuck 230, pressing the center of the upper wafer W1.

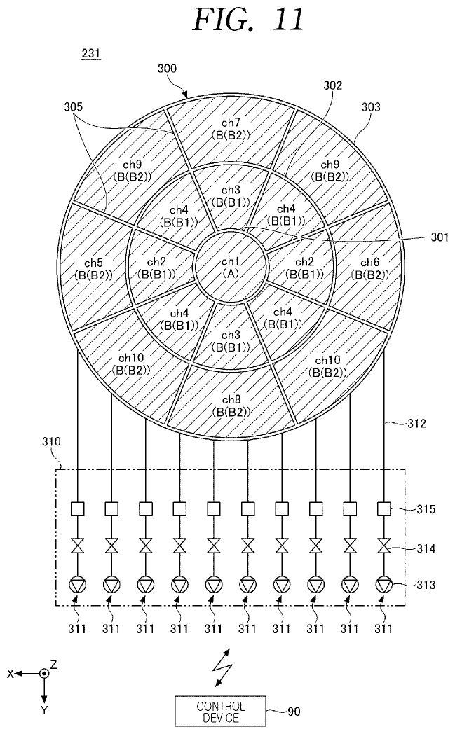

Moreover, the lower chuck 231 also has a plurality of partitioned regions in an attraction surface 300 for attracting the lower wafer W2. A top surface of the lower chuck 231 is provided with ribs 301, 302 and 303 each having an annular shape and a rib 305 having a radial shape (see FIG. 11). The attraction surface 300 is formed by upper ends of the ribs 301, 302, and 305. The configuration of the attraction surface 300 of the lower chuck 231 will be described in detail later.

The lower chuck 231 is provided with a plurality of (for example, three) lift pins 265 configured to be movable up and down in a vertical direction. The plurality of lift pins 265 are protruded from the attraction surface 300 of the lower chuck 231 as they are raised. Further, the lift pins 265 receive the lower wafer W2 as they are raised with respect to the lower wafer W2 carried in by the transfer device 61. Furthermore, the lift pins 265 are lowered after the transfer device 61 is retreated, thus allowing the lower wafer W2 to be placed on the attraction surface 300. Also, the lift pins 265 may vacuum-attract the lower wafer W2 when they receive the lower wafer W2.

In addition, the lower chuck 231 according to the present exemplary embodiment is configured to transform the attraction surface 300. The lower chuck 231 includes, for example, a base 232 and an attraction member 233. The attraction member 233 is provided above the base 232 to attract and hold the lower wafer W2 from below. The attraction member 233 is formed in a circular shape with a diameter larger than that of the lower wafer W2 when viewed from the top, and is fixed to the base 232 by a fastening ring 234 provided at a periphery thereof. The attraction member 233 is made of, for example, ceramic such as alumina or silicon carbide.

In addition, the lower chuck 231 has a pressure-variable space 235 between a top surface of the base 232 and a bottom surface of the attraction member 233, and is equipped with a transformation adjuster 236 configured to elastically transform the attraction member 233 by varying the pressure of the pressure-variable space 253. In other words, the attraction member 233, the pressure variable space 235, and the transformation adjuster 236 constitute a transforming device configured to transform the lower chuck 231.

The transformation adjuster 236 includes a vacuum pump 236a, a booster pump 236b, and a switching valve 236c. The vacuum pump 236a decompresses the pressure-variable space 235 by discharging a gas in the pressure-variable space 235. As the pressure-variable space 235 is decompressed, a top surface of the attraction member 233 becomes a horizontal surface or a curved surface with a recessed center side. Meanwhile, the booster pump 236b pressurizes the pressure-variable space 235 by supplying a gas to the pressure-variable space 235. As the pressure-variable space 235 is pressurized, the attraction surface 300 becomes a curved surface with a protruding center side. A transformation amount of the attraction surface 300 may be adjusted by controlling the pressure of the pressure variable space 235. The switching valve 236c switches the pressure-variable space 235 between a state in which it is connected to the vacuum pump 236a and a state in which it is connected to the booster pump 236b.

The base 232 has a measurer 237 configured to measure a protrusion amount of a central region A of the attraction surface 300. A measurement target 237a of the measurer 237 is moved up and down along with a central portion of the attraction member 233. The measurer 237 is, for example, a capacitance sensor, and measures the protrusion amount by detecting electrostatic capacitance which varies depending on a distance with respect to the measurement target 237a.

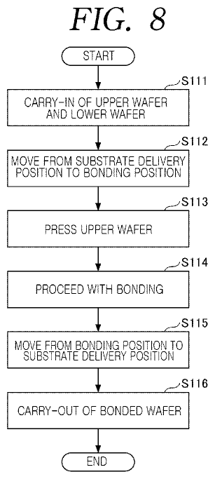

Now, with reference to FIG. 8 to FIG. 10C, the process of manufacturing the bonded wafer T in the process S109 of FIG. 4 will be described in detail. As depicted in FIG. 8, the control device 90 controls the transfer device 61 to carry the upper wafer W1 and the lower wafer W2 into the bonding module 41 (process S111). The relative positions of the upper chuck 230 and the lower chuck 231 after being carried in are at the substrate delivery position, as illustrated in FIG. 5 and FIG. 6.

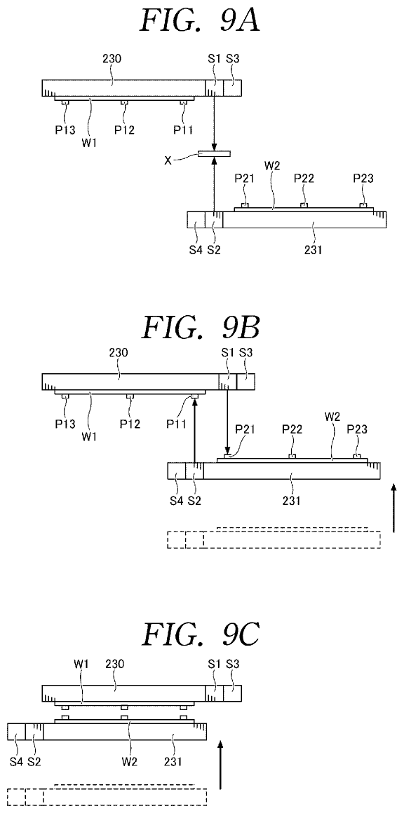

Subsequently, the control device 90 controls the moving mechanism 290 to move the relative positions of the upper chuck 230 and the lower chuck 231 from the substrate delivery position to the bonding position shown in FIG. 7 (process S112). In this process S112, the control device 90 carries out position-alignment between the upper wafer W1 and the lower wafer W2 by using a first camera S1 and a second camera S2 as shown in FIG. 9A to FIG. 9C.

The first camera S1 is fixed to the upper chuck 230 to image the lower wafer W2 held by the lower chuck 231. Multiple reference points P21 to P23 are previously formed on the bonding surface W2j of the lower wafer W2. As the reference points P21 to P23, patterns of electronic circuits, electrode pads, or the like may be used. The number of the reference points is not particularly limited.

Meanwhile, the second camera S2 is fixed to the lower chuck 231 to image the upper wafer W1 held by the upper chuck 230. Multiple reference points P11 to P13 are formed in advance on the bonding surface W1j of the upper wafer W1. As the reference points P11 to P13, patterns of electronic circuits or the like may be used. The number of these reference points is not particularly limited.

As depicted in FIG. 9A, the bonding module 41 adjusts the relative positions of the first camera S1 and the second camera S2 in a horizontal direction through the use of the moving mechanism 290. Specifically, the moving mechanism 290 moves the lower chuck 231 in the horizontal direction such that the second camera S2 is positioned substantially directly below the first camera S1. Then, the first camera S1 and the second camera S2 image a common target X and the moving mechanism 290 finely adjusts the position of the second camera S2 in the horizontal direction such that the positions of the first camera S1 and the second camera S2 in the horizontal direction are coincident.

Subsequently, as shown in FIG. 9B, the moving mechanism 290 moves the lower chuck 231 vertically upwards to adjust the positions of the upper chuck 230 and the lower chuck 231 in the horizontal direction. Specifically, while the moving mechanism 290 moves the lower chuck 231 in the horizontal direction, the first camera S1 sequentially images the reference points P21 to P23 of the lower wafer W2, and the second camera S2 sequentially images the reference points P11 to P13 of the upper wafer W1. FIG. 9B shows a state in which the first camera S1 is imaging the reference point P21 of the lower wafer W2 and the second camera S2 is imaging the reference point P11 of the upper wafer W1.

The first camera S1 and the second camera S2 transmit the obtained image data to the control device 90. The control device 90 controls the moving mechanism 290 based on the image data obtained by the first camera S1 and the image data obtained by the second camera S2, and adjusts the position of the lower chuck 231 in the horizontal direction such that the reference points P11 to P13 of the upper wafer W1 and the reference points P21 to P23 of the lower wafer W2 coincide with each other when viewed from the vertical direction.

Thereafter, as illustrated in FIG. 9C, the moving mechanism 290 moves the lower chuck 231 vertically upwards. As a result, a distance G (see FIG. 7) between the bonding surface W2j of the lower wafer W2 and the bonding surface W1j of the upper wafer W1 becomes a predetermined distance of, e.g., 80 μm to 200 μm. The adjustment of the distance G is performed by using a first displacement meter S3 and a second displacement meter S4.

The first displacement meter S3 is fixed to the upper chuck 230, and measures the thickness of the lower wafer W2 held by the lower chuck 231. The first displacement meter S3 measures the thickness of the lower wafer W2 by, for example, radiating light to the lower wafer W2 held by the lower chuck 231 and receiving reflected light reflected from both top and bottom surfaces of the lower wafer W2. This thickness measurement is performed when the moving mechanism 290 moves the lower chuck 231 in the horizontal direction, for example. The first displacement meter S3 carries out the measurement by, for example, a confocal method, a spectral interference method, or a triangulation method. A light source of the first displacement meter S3 may be an LED or a laser.

Meanwhile, the second displacement meter S4 is fixed to the lower chuck 231, and measures the thickness of the upper wafer W1 held by the upper chuck 230. The second displacement meter S4 measures the thickness of the upper wafer W1 by, for example, radiating light to the upper wafer W1 held by the upper chuck 230 and receiving reflected light reflected from both top and bottom surfaces of the upper wafer W1. This thickness measurement is performed when the moving mechanism 290 moves the lower chuck 231 in the horizontal direction, for example. The second displacement meter S4 carries out the measurement by, for example, a confocal method, a spectral interference method, or a triangulation method. A light source of the second displacement meter S4 may be an LED or a laser.

The first displacement meter S3 and the second displacement meter S4 transmit the measured data to the control device 90. The control device 90 controls the moving mechanism 290 based on the data obtained by the first displacement meter S3 and the data obtained by the second displacement meter S4, and adjusts the position of the lower chuck 231 in the vertical direction such that the distance G becomes a set value.

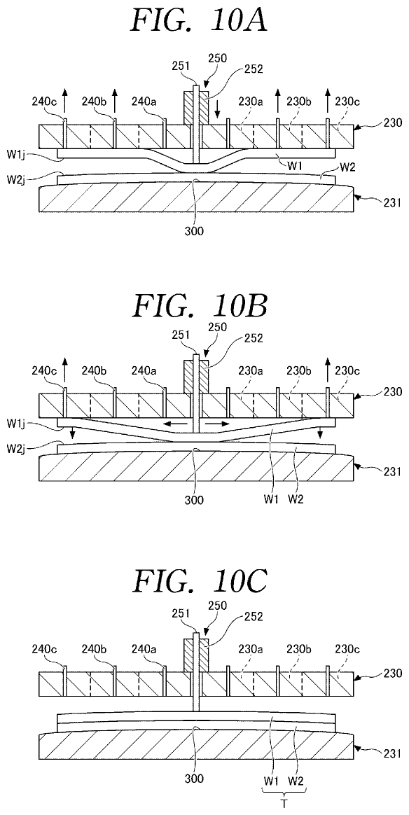

Next, after the distance G between the upper wafer W1 and the lower wafer W2 is adjusted, the operation of the vacuum pump 241a is stopped, thus canceling the vacuum attraction of the upper wafer W1 in the region 230a, as shown in FIG. 10A. Thereafter, the pushing pin 251 of the pushing member 250 is lowered to press the center of the upper wafer W1, allowing the upper wafer W1 to come into contact with the lower wafer W2 (process S113). As a result, the centers of the upper wafer W1 and the lower wafer W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j, so that the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, allowing the bonding surfaces W1j and W2j to be firmly bonded to each other.

Subsequently, the control device 90 stops the operation of the vacuum pump 241b, and cancels the vacuum attraction of the upper wafer W1 in the region 230b, as shown in FIG. 10B. Afterwards, the control device 90 stops the operation of the vacuum pump 241c, and cancels the vacuum attraction of the upper wafer W1 in the region 230c, as shown in FIG. 10C.

In this way, the vacuum attraction of the upper wafer W1 is released step by step from the center toward a periphery of the upper wafer W1, so that the upper wafer W1 drops and comes into contact with the lower wafer W2 step by step. Then, the bonding of the upper wafer W1 and the lower wafer W2 proceeds sequentially toward the peripheries of the upper and lower wafers W1 and W2 from the centers thereof (process S114). As a result, the entire bonding surface W1j of the upper wafer W1 and the entire bonding surface W2j of the lower wafer W2 come into contact with each other, so that the upper wafer W1 and the lower wafer W2 are bonded together, and the bonded wafer T is obtained. Then, the bonding apparatus 1 raises the pushing pin 251 to its original position.

Referring back to FIG. 8, after the bonded wafer T is formed, the control device 90 controls the moving mechanism 290 to move the relative positions of the upper chuck 230 and the lower chuck 231 from the bonding positions shown in FIG. 7 to the substrate delivery positions shown in FIG. 5 and FIG. 6 (process S115). By way of example, the moving mechanism 290 first lowers the lower chuck 231 to widen the distance between the lower chuck 231 and the upper chuck 230 in the vertical direction. Then, the moving mechanism 290 moves the lower chuck 231 sideways so that the lower chuck 231 and the upper chuck 230 are placed sideways apart.

Thereafter, the control device 90 controls the transfer device 61 to carry out the bonded wafer T from the bonding module 41 (process S116). Specifically, the lower chuck 231 first releases the holding of the bonded wafer T. Then, the plurality of lift pins 265 are raised to hand the bonded wafer T over to the transfer device 61. Thereafter, the plurality of holding pins 265 are lowered to their original positions.

Now, the configuration of the attraction surface 300 of the lower chuck 231 will be described with reference to FIG. 11. FIG. 11 is a plan view illustrating the attraction surface 300 of the lower chuck 231. The attraction surface 300 of the lower chuck 231 has a plurality of regions that are arranged in a radial direction thereof to generate an attracting pressure individually.

For example, the attraction surface 300 is partitioned into a central region A of a circular shape and an outer region B of an annular shape by annular ribs 301, 302, and 303. Further, the outer region B includes a first outer region B1 of an annular shape outside and adjacent to the central region A; and a second outer region B2 of an annular shape outside and adjacent to the first outer region B1. That is, the central region A, the first outer region B1, and the second outer region B2 are concentrically arranged in this order radially outwards from a center of the attraction surface 300. Alternatively, the first outer region B1 and the second outer region B2 may not be separated, and the attraction surface 300 may be partitioned into the central region A and the single outer region B that are arranged in this order radially outwards. To the contrary, the outer region B of the attraction surface 300 may include three or more annular regions.

The first outer region B1 is divided into eight arc-shaped zones (small regions: one part) by a plurality of ribs 305 that are arranged radially. Likewise, the second outer region B2 is also divided into eight arc-shaped zones by the ribs 305. Here, the number of the divisions of the first outer region B1 may be equal to or different from the number of the divisions of the second outer region B2, and their positions in a circumferential direction may be deviated from each other.

The central region A, the eight zones of the first outer region B1, and the eight zones of the second outer region B2 are configured to be capable of suctioning the lower wafer W2 individually. Here, however, in the lower chuck 231 according to the present exemplary embodiment, ten adjusting mechanisms 311 are connected to the total of seventeen zones, and the attraction surface 300 are suctioned for the zones of ten channels. That is, the attraction surface 300 has, among the total of seventeen zones, zones in which the suctioning is performed by the same adjusting mechanism 311. Further, in FIG. 11, each zone in which the suctioning is performed (in which the attracting pressure is generated) is illustrated by a single hatching.

To be more specific, the central region A is comprised of a single zone ch1. Meanwhile, in the first outer region B1, three zones ch2 to ch4 are set. The two zones adjacent to each other in the X-axis direction (a left-and-right direction in FIG. 11) with the central region A therebetween are the zones ch2. The two zones adjacent to each other in the Y-axis direction (an up-and-down direction in FIG. 11) with the central region A therebetween are the zones ch3. Further, in the outer region B, the four zones interposed between the zones ch2 and the zones ch3 are the zones ch4. In the second outer region B2, six zones ch5 to ch10 are set. The one zone adjacent to the first outer region B1 in the positive X-axis direction (left side in FIG. 11) is the zone ch5. The one zone adjacent to the first outer region B1 in the negative X-axis direction (right side in FIG. 11) is the zone ch6. The one zone adjacent to the first outer region B1 in the negative Y-axis direction (upper side in FIG. 11) is the zone ch7. The one zone adjacent to the first outer region B1 in the positive Y-axis direction (lower side in FIG. 11) is the zone ch8. Further, in the second outer region B2, the zone interposed between the zone ch5 and the zone ch7 and the zone interposed between the zone ch6 and the zone ch7 are the zones ch9. Likewise, in the second outer region B2, the zone interposed between the zone ch5 and the zone ch8 and the zone interposed between the zone ch6 and the zone ch8 are the zones ch10.

On the X-axis passing through the center of the attraction surface 300, the zones of ch5, ch2, ch1, ch2, and ch6 are arranged in this sequence from the positive X-axis side toward the negative X-axis side. On the Y-axis passing through the center of the attraction surface 300, the zones of ch7, ch3, ch1, ch3, and ch8 are arranged in this sequence from the negative Y-axis side toward the positive Y-axis side. Here, however, it should be noted that the attraction surface 300 can be designed as required for the number and the location of the channels of the respective zones without being limited to the shown example.

Connected to the lower chuck 231 is an attracting pressure generator 310 configured to perform suctioning or discharging of air to the respective zones of the attraction surface 300 (see FIG. 7 as well). Specifically, the attracting pressure generator 310 is equipped with ten adjusting mechanisms 311 respectively connected to the ten channels. Further, the attracting pressure generator 310 is connected to the control device 90 so as to communicate with it, and operates the respective adjusting mechanism 311 under the control of the control device 90.

Each adjusting mechanism 311 has a flow line 312 connected to the predetermined zone of the lower chuck 231, and a suction pump 313, an opening/closing valve 314, and a pressure controller 315 are provided on this flow line 312. Each zone has, inside each surrounding rib (top surface of the attraction member 233), a plurality of holes (not shown) communicating with the flow line 312.

Each adjusting mechanism 311 opens the opening/closing valve 314 by operating the suction pump 313 of the flow line 312, thus generating an attracting pressure (negative pressure) in the respective holes of the channel to which the flow line 312 is connected. The magnitude of the attracting pressure is controlled by the pressure controller 315. Further, each adjusting mechanism 311 cancels the attracting pressure of each zone by closing the opening/closing valve 314 of the preset flow line 312 and introducing air through the pressure controller 315.

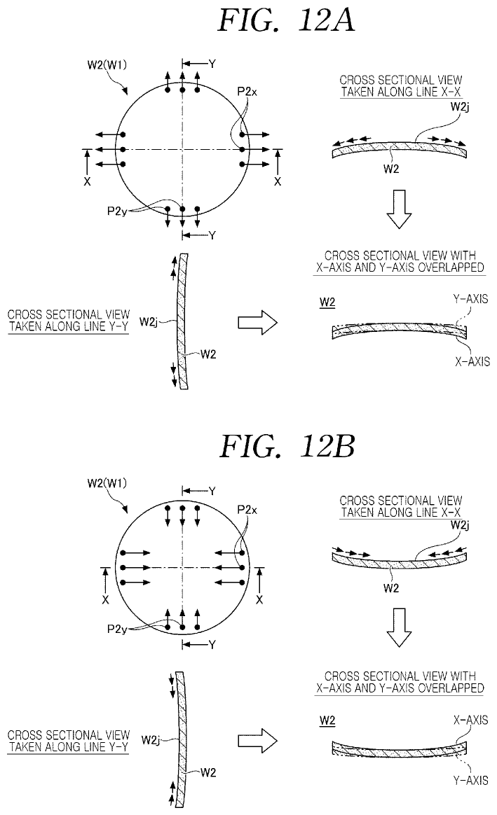

Here, the upper wafer W1 and the lower wafer W2 bonded by the bonding apparatus 1 may be bent as a whole, as shown in FIG. 12A. The bending of the upper wafer W1 and the lower wafer W2 occurs when a plurality of films are stacked on a semiconductor substrate such as a silicon wafer, for example. Each film is formed by a CVD (Chemical Vapor Deposition) method, an ALD (Atomic Layer Deposition) method, a spin-on method, or the like. A stress is applied to the upper wafer W1 and the lower wafer W2 due to a difference in thermal expansion during the film formation, causing the upper wafer W1 and the lower wafer W2 to be bent.

The upper wafer W1 and the lower wafer W2 are often symmetrically bent with respect to two orthogonal straight lines in the radial direction, that is, axisymmetrically bent. This is because a Young's modulus, a Poisson's ratio, and a shear modulus of the semiconductor substrate such as the silicon wafer change at a cycle of 90°. The two orthogonal straight lines in the radial direction extend along a specific crystal orientation of the semiconductor substrate when viewed from a direction (Z-axis direction) perpendicular to the attraction surface 300.

The bending of the upper wafer W1 and the lower wafer W2 is measured by, for example, a bending measurement device 5 (see FIG. 1) provided separately from the bonding apparatus 1. When the control device 90 acquires information on the bending state of the lower wafer W2 measured by the bending measurement device 5, the control device 90 maintains this information on the bending state in the memory 92 during the processing of the upper wafer W1 and the lower wafer W2. Further, the bending measurement device 5 may be provided as a part of the bonding apparatus 1. The bonding apparatus 1 may be configured to measure the bending when carrying in the upper wafer W1 or the lower wafer W2 by using a plurality of displacement meters (not shown) provided in the bonding module 41. The bending is measured when no external force (for example, attracting pressure) other than gravity and its reaction force is acting, for example, measured in a state that it is placed on a flat surface of a stage or on a plurality of (e.g., three) pins.

Then, based on the information on the bending state of the upper wafer W1, the bonding apparatus 1 moves the upper wafer W1 from the transfer device 61 to the upper chuck 230 so that two orthogonal straight lines in the radial direction with large bending in the upper wafer W1 are aligned with the X-axis direction and the Y-axis direction of the upper chuck 230. For example, the posture of the upper wafer W1 is adjusted by the above-described first position adjusting device 51 (see FIG. 2). In addition, based on the information on the bending state of the lower wafer W2, the bonding apparatus 1 moves the lower wafer W2 from the transfer device 61 to the lower chuck 231 so that two orthogonal straight lines in the radial direction with large bending in the lower wafer W2 are aligned with the X-axis direction and the Y-axis direction of the lower chuck 231. For example, the posture of the lower wafer W2 is adjusted by the second position adjusting device 52 (see FIG. 2) described above.

The bending of the upper wafer W1 and the lower wafer W2 is either in a form in which outer edges thereof at symmetrical positions are bent in a direction in which they get closer to the attraction surface 300 than the centers thereof, or in a form in which the outer edges at the symmetrical positions are bent in a direction in which they get away from the attraction surface 300 than the centers thereof. Hereinafter, the form in which the outer edge of the lower wafer W2 is bent in the direction in which it gets closer to the attraction surface 300 in the state that the lower wafer W2 is disposed on the attraction surface 300 before being attracted is referred to as a convex bending. Further, the form in which the outer edge of the lower wafer W2 is bent in the direction in which it gets away from the attraction surface 300 in the state that the lower wafer W2 is placed on the attraction surface 300 before being attracted is referred to as a concave bending.

When the convex bending has occurred in the lower wafer W2, the outer edges at both ends on the X-axis (first axis) and the outer edges at both ends on the Y-axis (second axis) are gently curved with respect to the center in a direction (vertically downward direction) in which they get closer to the attraction surface 300, as illustrated on cross sections taken along lines X-X and Y-Y of FIG. 12A. However, a bending amount along the X-axis and a bending amount along the Y-axis are not necessarily same. As mentioned above, this is because the Young's modulus, the Poisson's ratio, and the shear modulus change at a cycle of 90°. In addition, in the present specification, the term “bending amount” refers to a length between a height position of the center and a height position of the outer edge when the plate thickness of the lower wafer W2 (or upper wafer W1) is aligned in a vertical direction.

For example, in the example of FIG. 12A, the bending amount on the X-axis is large, while the bending amount on the Y-axis is small. Accordingly, on the X-axis of the top surface (boding surface W2j) of the lower wafer W2, a stress causing the lower wafer W2 to be stretched in a radially outward direction is applied, so that respective reference points P2x on the X-axis of the top surface of the lower wafer W2 are largely moved radially outwards. Meanwhile, the Y-axis of the top surface of the lower wafer W2, a stress causing the lower wafer W2 to be slightly stretched in the radially outward direction is applied, so that respective reference points P2y on the Y-axis of the top surface of the lower wafer W2 are slightly moved outwards in the radial direction.

In addition, when the concave bending has occurred in the lower wafer W2, the outer edges at both ends on the X-axis and the outer edges at both ends on the Y-axis are gently curved with respect to the center in a direction (vertically upward direction) in which they get away from the attraction surface 300, as illustrated on cross sections taken along lines X-X and Y-Y of FIG. 12B. Further, in the example of FIG. 12B, the bending amount on the X-axis is large, while the bending amount on the Y-axis is small. Accordingly, on the X-axis of the top surface of the lower wafer W2, a stress causing the lower wafer W2 to be largely contracted in a radially inward direction is applied, so that the respective reference points P2x on the X-axis of the top surface of the lower wafer W2 are largely moved radially inwards. Meanwhile, on the Y-axis of the top surface of the lower wafer W2, a stress causing the lower wafer W2 to be slightly contracted in the radially inward direction is applied, so that the respective reference points P2y on the Y-axis of the top surface of the lower wafer W2 are slightly moved inwards in the radial direction.

Furthermore, although not shown, the upper wafer W1 to be attracted to and held by the upper chuck 230 may also undergo a convex bending or a concave bending. The convexly bent upper wafer W1 has a form in which the outer edge thereof is bent in a direction (vertically upward direction) in which it gets closer to the attraction surface of the upper chuck 230 as compared to the center thereof in the state that the upper wafer W1 faces the upper chuck 230 before being attracted. Even if the upper chuck 230 has attracted the convexly bent upper wafer W1 on the flat attraction surface thereof, the convexly bent upper wafer W1 has, on the X-axis or Y-axis of the bottom surface (bonding surface W1j) thereof, a potential inherent stress causing it to be extended outwards in the radial direction. Meanwhile, the concavely bent upper wafer W1 has a form in which the outer edge thereof is bent in a direction (vertically downward direction) in which it gets away from the attraction surface of the upper chuck 230 as compared to the center thereof in the state that the upper wafer W1 faces the upper chuck 230 before being attracted. Even if the concavely bent upper wafer W1 is attracted to the flat attraction surface of the upper chuck 230, the concavely bent upper wafer W1 has, on the X-axis or Y-axis of the bottom surface (bonding surface W1j), a potential inherent stress causing it to be contracted inwards in the radial direction.

In view of the foregoing, the bonding apparatus 1 according to the present exemplary embodiment is configured to move the respective reference points P2x and P2y of the lower wafer W2 based on the bending state of the upper wafer W1 and the bending state of the lower wafer W2 when placing the lower wafer W2 on the lower chuck 231. To be specific, based on the bending state of the upper wafer W1 and the bending state of the lower wafer W2, the bonding apparatus 1 sets a zone in which the attraction surface 300 attracts the lower wafer W2, and performs an operation of stretching the top surface of the lower wafer W2 by transforming the attraction surface 300 of the lower chuck 231.

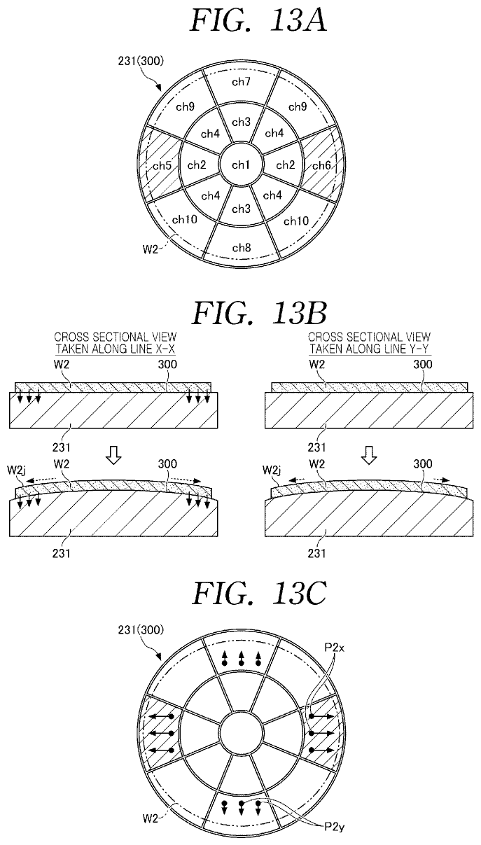

Hereinafter, referring to FIG. 13A to FIG. 13C, an operation whereby the lower chuck 231 attracts the lower wafer W2 will be described in detail. FIG. 13A to FIG. 13C illustrate an example of attracting the lower wafer W2 on the X-axis of the lower chuck 231.

Before transforming the attraction surface 300 of the lower chuck 231, the control device 90 first places the lower wafer W2 on the attraction surface 300 to partially attract the lower wafer W2. To attract the lower wafer W2, the zone of the attraction surface 300 corresponding to a portion of the boding surface W2j of the lower wafer W2 intended to be largely stretched is calculated, and an attracting pressure is applied to that zone. For example, in FIG. 13A and FIG. 13B, in order to attract the vicinity of the outer edge of the lower wafer W2 on the X-axis, the control device 90 controls the attracting pressure generator 310 to apply the attracting pressure to the zones of ch5 and ch6, which are parts of the outer region B in the circumferential direction. At this time, the control device 90 does not apply the attracting pressure to the other zones in the outer region B.

The zones of ch5 and ch6 attracts the bottom surface (non-bonding surface W2n) of the lower wafer W2 by the attracting pressure. Accordingly, as shown in FIG. 13B, the lower chuck 231 firmly holds (fixes) the vicinity of the outer edge of the lower wafer W2 on the X-axis on the attraction surface 300 thereof before the attraction surface 300 is transformed. Then, while holding the vicinity of the outer edge of the lower wafer W2 on the X-axis, the control device 90 transforms the central region A of the attraction surface 300 such that the central region A is raised higher than the outer edge of the attraction surface 300. Following the transformation of the attraction surface 300 of the lower chuck 231, the lower wafer W2 is also transformed into a shape in which the center thereof is raised higher than the outer edge thereof.

When the attraction surface 300 is transformed, the lower wafer W2 is held by the zones of ch5 and ch6 of the lower chuck 231 on the X-axis. For this reason, the top surface (bonding surface W2j) of the lower wafer W2 that is attracted is largely stretched along the X-axis. Conversely, the vicinity of the outer edge of the lower wafer W2 on the Y-axis is set as a free end that is not attracted to the attraction surface 300 when the attraction surface 300 is transformed. For this reason, although the top surface of the lower wafer W2 on the Y-axis also stretched, the stretched amount becomes smaller than that on the X-axis.

That is, as shown in FIG. 13C, in the lower wafer W2 after the attraction surface 300 is transformed, the respective reference points P2x on the X-axis are largely moved outwards in the radial direction. Further, the respective reference point P2y on the Y-axis are slightly moved outwards in the radial direction. In addition, in FIG. 13C, although moving amounts of the respective reference points P2x and the respective reference points P2y are indicated by the lengths of arrows in an exaggerated manner, actual movements of the respective reference points P2x and the respective reference points P2y are merely on the order of several μm to several mm.

Here, it is apparent that the operation of transforming the attraction surface 300 by attracting the lower wafer W2 through the lower chuck 231 before transforming the attraction surface 300 is not limited to the X-axis of the lower chuck 231. The control device 90 may transform the attraction surface 300 by attracting the non-bonding surface W2n of the lower wafer W2 through the zones of ch7 and ch8 of the lower chuck 231 on the Y axis. As a result, the Y-axis of the bonding surface W2j of the lower wafer W2 is largely stretched, whereas the X-axis of the bonding surface W2j of the lower wafer W2 is slightly stretched.

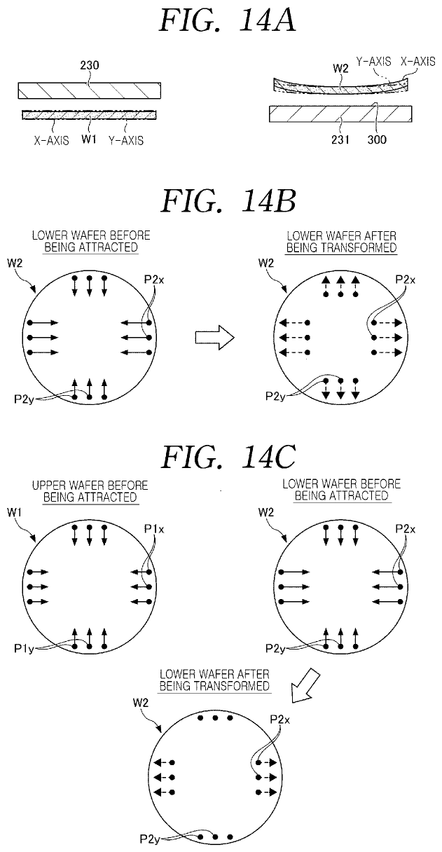

Regarding the above-described operation of transforming the attraction surface 300 by attracting the lower wafer W2 through the lower chuck 231, the control device 90 makes a determination upon whether or not to perform the operation and how to set the zone(s) to perform the attraction based on the bending states of the upper wafer W1 and the lower wafer W2. For example, as shown in FIG. 14A, when the upper wafer W1 is not bent and the bending amount of the concavely bent lower wafer W2 on the X-axis is larger than the bending amount on the Y-axis, the control device 90 makes a decision to attract the X-axis of the lower wafer W2. In this relationship, it is deemed that the bending amount of the lower wafer W2 on the X-axis is large, and the bonding surface W2j of the lower wafer W2 having this large bending amount needs to be stretched.

That is, as shown in the left drawing of FIG. 14B, in the lower wafer W2 before being attracted, the respective reference points P2x on the X-axis are largely moved inwards in the radial direction, whereas the respective reference points P2y on the Y-axis are slightly moved inwards in the radial direction. In this case, the control device 90 makes a determination to generate the attracting pressure in the zones ch5 and ch6 of the attraction surface 300 facing the portions with the large bending amount. The lower chuck 231 generates the attracting pressure in the zones of ch5 and ch6 under the control of the control device 90 to firmly hold the vicinity of the outer edge of the lower wafer W2 on the X-axis, and then transforms the attraction surface 300. At this time, based on the bending amount of the lower wafer W2, the control device 90 may appropriately adjust a protrusion amount by which the center of the attraction surface 300 is protruded with respect to outer edge thereof.

As a result, the X-axis of the bonding surface W2j of the lower wafer W2 is largely stretched, offsetting the stress in the contracting direction on the X-axis. Further, the Y-axis of the bonding surface W2j of the lower wafer W2 is slightly stretched, offsetting the stress in the contracting direction on the Y-axis. Therefore, as shown in the right drawing of FIG. 14B, the respective reference points P2x and P2y of the lower wafer W2 after the attraction surface 300 is transformed overlap well with the respective reference points of the upper wafer W1 when the upper wafer W1 and the lower wafer W2 are bonded in the bonding apparatus 1.

Furthermore, when the lower wafer W2 placed on the lower chuck 231 is convexly bent, the bonding surface W2j is stretched outwards in the radial direction. In this case, the control device 90 needs to generate the attracting pressure in the zone(s) facing the X-axis or the Y-axis of the lower wafer W2, whichever has a smaller bending amount. Accordingly, the respective reference points on the axis with a relatively small extension can be aligned with the respective reference points on the axis with a relatively large extension.

In addition, when the upper wafer W1 is slightly bent as shown in FIG. 14C, the control device 90 needs to appropriately control the operation of the lower chuck 231 such that the respective reference points of the upper wafer W1 are aligned with the respective reference points of the lower wafer W2. For example, when the respective reference points P1x of the upper wafer W1 on the X-axis and the respective reference points P1y of the upper wafer W1 on the Y-axis are deviated inwards in the radial direction as the upper wafer W1 is concavely bent, the lower chuck 231 is operated to match the deviations of the reference points P1x and P1y of the upper wafer W1 with the deviations of the reference points P2x and P2y of the lower wafer W2. In the example of FIG. 14C, by reducing the deviations of the reference points P1x and P1y of the upper wafer W1 from the deviations of the reference points P2x and P2y of the lower wafer W2, the reference points are mutually aligned. Then, the control device 90 controls the operation of the lower chuck 231 according to the reference points P2x and P2y of the lower wafer W2 after the reduction of the deviations. In the example of FIG. 14C, by adjusting the protrusion amount of the attraction surface 300 after attracting the X-axis of the lower wafer W2 by the lower chuck 231, the respective reference points P2x of the lower wafer W2 may be moved shortly outwards in the radial direction.

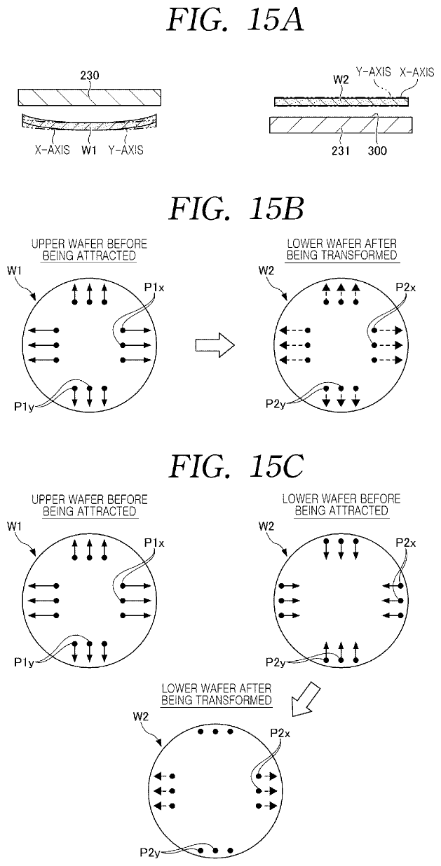

As illustrated in FIG. 15A, when the lower wafer W2 is not bent in the state that the bending amount of the convexly bent upper wafer W1 on the X-axis is larger than the bending amount on the Y-axis, the control device 90 also makes a decision to attract the X-axis of the upper wafer W2. In this relationship, it is deemed that as the influence of the bending of the upper wafer W1 on the X-axis is large, the bonding surface W2j of the lower wafer W2 corresponding thereto needs to be stretched.

That is, as shown in the left drawing of FIG. 15B, in the upper wafer W1 before being attracted, the respective reference points P1x on the X-axis are largely moved outwards in the radial direction, whereas the respective reference points P1y on the Y-axis are slightly moved outwards in the radial direction. In this case, the control device 90 makes a decision to generate the attracting pressure in the zones ch5 and ch6 of the attraction surface 300. The lower chuck 231 generates the attracting pressure in the zones ch5 and ch6 under the control of the control device 90 to firmly hold the vicinity of the outer edge of the lower wafer W2 on the X-axis, and then transforms the attraction surface 300. At this time, based on the bending amount of the upper wafer W1, the control device 90 may appropriately adjust the protrusion amount by which the center of the attraction surface 300 is protruded with respect to outer edge thereof.

As a result, the X-axis of the bonding surface W2j of the lower wafer W2 is largely stretched, and it becomes possible to align the respective reference points P2x of the lower wafer W2 on the X-axis with the respective reference points P1x of the upper wafer W1 on the X-axis. In addition, the Y-axis of the bonding surface W2j of the lower wafer W2 is slightly stretched, and the respective reference points P2y of the lower wafer W2 on the Y-axis can be aligned with the respective reference points P1y of the upper wafer W1 on the Y-axis. Therefore, the respective reference points P2x and P2y of the lower wafer W2 after the attraction surface 300 is transformed are made to overlap well with the respective reference points P1x and P1y of the upper wafer W1 when the upper wafer W1 and the lower wafer W2 are bonded in the bonding apparatus 1.

Additionally, as shown in FIG. 15C, when the lower wafer W2 is slightly bent, the control device 90 needs to appropriately control the operation of the lower chuck 231 such that the respective reference points of the upper wafer W1 and the respective reference points of the lower wafer W2 are aligned. For example, when the respective reference points P2x of the lower wafer W2 on the X-axis and the respective reference points P2y thereof on the Y-axis are deviated inwards in the radial direction as the lower wafer W2 is concavely bent, the lower chuck 231 is operated to match the deviations of the reference points P1x and P1y of the upper wafer W1 with the deviations of the reference points P2x and P2y of the lower wafer W2. In the example of FIG. 15C, by adding the deviations of the reference points P2x and P2y of the lower wafer W2 to the deviations of the reference points P1x and P1y of the upper wafer W1, the reference points are mutually aligned. Then, the control device 90 controls the operation of the lower chuck 231 according to the reference points P1x and P1y of the upper wafer W1 after the addition of the deviations. In the example of FIG. 15C, by adjusting the protrusion amount of the attraction surface 300 after attracting the X-axis of the lower wafer W2 by the lower chuck 231, the respective reference points P2x of the lower wafer W2 may be moved shortly outwards in the radial direction.

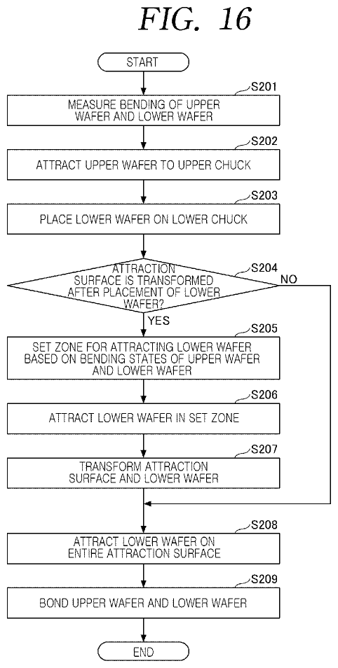

The bonding apparatus 1 according to the present exemplary embodiment is basically configured as described above, and its operation will be described below with reference to a flowchart of FIG. 16.

As depicted in FIG. 16, in a bonding method, before the upper wafer W1 and the lower wafer W2 to be bonded together are carried into the bonding apparatus 1, bending of the upper wafer W1 and the lower wafer W2 are measured by the bending measurement device 5 (process S201). The control device 90 acquires information on the bending states of the upper wafer W1 and the lower wafer W2 from the bending measurement device 5. The measurement of the upper wafer W1 and the lower wafer W2 by the bending measurement device 5 may be performed automatically by transferring the wafers to the bending measurement device 5 by using a non-illustrated transfer device, or may be performed manually by a user.

Subsequently, after processing the upper wafer W1 according to the respective processes S101 to S104 of FIG. 4, the control device 90 carries the upper wafer W1 into the bonding module 41 by the transfer device 61, and allows the upper wafer W1 to be attracted to the upper chuck 230 (process S202 in FIG. 16). Further, after processing the lower wafer W2 according to the respective processes S105 to S108 of FIG. 4, the control device 90 places the lower wafer W2 on the lower chuck 231 (process S203 of FIG. 16). The operations of these processes S202 and S203 are the same as the operation of process S111 in FIG. 8.

Further, during the transfer of the upper wafer W1 and the lower wafer W2, or the like, the control device 90 makes a determination, based on the measured bending states of the upper wafer W1 and the lower wafer W2, upon whether or not to transform the attraction surface 300 after the lower wafer W2 is placed on the attraction surface 300 (process S204). By way of example, when the bending states (bending amount, bending direction, etc.) of the upper wafer W1 and the lower wafer W2 are identical, in other words, when the respective reference points of the upper wafer W1 and the respective reference points of the lower wafer W2 are roughly aligned in advance, the control device 90 makes a decision not to transform the attraction surface 300. When the attraction surface 300 is not transformed (process S204: NO), the subsequent processes S205 to S207 are skipped, and the processing proceeds to a process S208. Meanwhile, when the bending states (bending amount, bending direction, etc.) of the upper wafer W1 and the lower wafer W2 are discrepant, the control device 90 makes a decision to transform the attraction surface 300 (process S204: YES), and proceeds to a process S205. To transform the attraction surface 300, the control device 90 sets a transformation amount (protrusion amount) of the attraction surface 300 based on the bending states (differences between the bending amounts in the respective bending directions) of the upper wafer W1 and the lower wafer W2.

Then, the control device 90 selects, among the respective zones of the lower chuck 231, a zone (a part) for attracting the lower wafer W2 based on the acquired bending states of the upper wafer W1 and the lower wafer W2 (process S205). By using previously acquired calculation formulas, map information, etc., as well as the bending states (differences between the bending amounts in the respective bending directions) of the upper wafer W1 and the lower wafer W2, the control device 90 selects a zone in which the respective reference points of the upper wafer W1 and the respective reference points of the lower wafer W2 can be aligned as stated above. Then, the control device 90 performs the following processes S206 to S208 before carrying out the process S112 of FIG. 8.

Specifically, the control device 90 operates the attracting pressure generator 310 to generate the attracting pressure in each zone set in the process S205, thus attracting the bottom surface (non-bonding surface W2n) of the lower wafer W2 facing each zone (process S206: process A). As a result, the vicinity of the outer edge of the lower wafer W2 on the X-axis or Y-axis is attracted to the set zone of the lower chuck 231.

Further, the control device 90 causes the central region A of the attraction surface 300 to be protruded with respect to the outer edge thereof while holding the lower wafer W2 (while continuing to attract the lower wafer W2), thus transforming the attraction surface 300 (process S207: process B). As a result, the lower wafer W2 is transformed to follow the transformation of the attraction surface 300, so that the respective reference points of the upper wafer W1 and the respective reference points of the lower wafer W2 are allowed to overlap each other at mutually facing positions during the bonding.

After the transformation of the attraction surface 300 (or after the placement of the lower wafer W2 when the attraction surface 300 is not transformed), the control device 90 operates the attracting pressure generator 310 to attract the lower wafer W2 on the entire attraction surface 300 (process S208). Also, at this time, the attracting pressure generator 310 may attract the lower wafer W2 while varying the attracting pressure between the respective channels individually. Through the operations of the processes S201 to S208 as described above, a substrate placing method of placing the lower wafer W2 on the lower chuck 231 is completed.

Finally, the control device 90 performs a bonding operation of bond the upper wafer W1 and the lower wafer W2 while holding the lower wafer W2 by the lower chuck 231 (process S209: process C). For this bonding operation, the processes S112 to S116 of FIG. 8 needs to be performed. By carrying out the above-described processing sequence, the bonding apparatus 1 is capable of bonding the upper wafer W1 and the lower wafer W2 with high precision in the state that the respective reference points of the upper wafer W1 and the respective reference points of the lower wafer W2 are aligned.

As described above, in the bonding apparatus 1 and the substrate placing method according to the present exemplary embodiment, in the state that the lower wafer W2 is attracted by generating the attracting pressure in some of the plurality of zones based on the bending state of the upper wafer W1 or the lower wafer W2, the attraction surface 300 is transformed. Therefore, even if there is a relative deviation between the reference points of the upper wafer W1 and the reference points of the lower wafer W2 due to, for example, a stress, such discrepancy between the respective reference points can be alleviated. As a result, in the bonding apparatus 1 and the substrate placing method, a stress distribution of the upper wafer W1 and the lower wafer W2 can be improved, so that the substrate can be maintained appropriately.

In particular, the bonding apparatus 1 is configured to transform the attraction surface 300 of the lower chuck 231 and not to transform the attraction surface of the upper chuck 230 between the upper chuck 230 and the lower chuck 231. Accordingly, in the process in which the upper wafer W1 is pressed by the pushing pin 251 and the upper wafer W1 are bonded from the center thereof, the upper wafer W1 can be stretched, and the lower wafer W2 is transformed by the attraction surface 300, so that the deviation between the respective reference points of the upper wafer W1 can be canceled. Moreover, the bonding apparatus 1 may be configured to transform the upper chuck 230 (upper wafer W1), or may be configured to transform both the upper chuck 230 and the lower chuck 231.

In addition, the bonding apparatus 1 can properly hold the lower wafer W2 on the attraction surface 300 by setting, based on the bending amount on the X-axis and the bending amount on the Y-axis, the zone in which the attracting pressure is generated. Further, the portion(s) of the bonding surface W2j of the lower wafer W2 that need to be stretched can be sufficiently stretched.

Then, by attracting the zones (for example, ch5 and ch6) at symmetrical positions with the central region A therebetween, the bonding apparatus 1 is capable of suppressing misalignment of the lower wafer W2 with respect to the lower chuck 231. In particular, by attracting the lower wafer W2 in each zone of the second outer region B2, the bonding apparatus 1 can successfully stretch the vicinity of the outer edge of the lower wafer W2 where a stress tends to manifest.

Further, the bonding apparatus 1 sets the zone for attracting the lower wafer W2 by taking the bending state of the upper wafer W1 into account, thus enabling the upper wafer W1 and the lower wafer W2 to face each other (enabling alignment between the respective reference points) with higher precision.

In addition, the bonding apparatus 1 and the substrate placing method according to the present exemplary embodiment are not limited to the above-described exemplary embodiments and can be modified in various ways. By way of example, the bonding apparatus 1 may generate different attracting pressures in the plurality of zones of the outer region B before transforming the attraction surface 300. As an example, a first attracting pressure may be applied to the zone(s) (for example, ch5 and ch6 on the X-axis) in which the lower wafer W2 needs to be largely stretched, and a second attracting pressure that is lower than the first attracting pressure may be applied to the zone(s) (for example, ch7 and ch8 on the Y-axis) in which the lower wafer W2 needs to be slightly stretched. Alternatively, the second attracting pressure lower than the first attracting pressure (or a third attracting pressure lower than the second attracting pressure) may be applied to the zones (for example, ch9 and ch10) in diagonal directions. In short, the attracting pressures of the respective zones before and during the transformation of the attraction surface 300 may be set as required. For example, in case that a portion of the bonding surface W2j that is required to be stretched most is in the diagonal direction, the attracting pressure in the diagonal direction may be set to be the strongest.

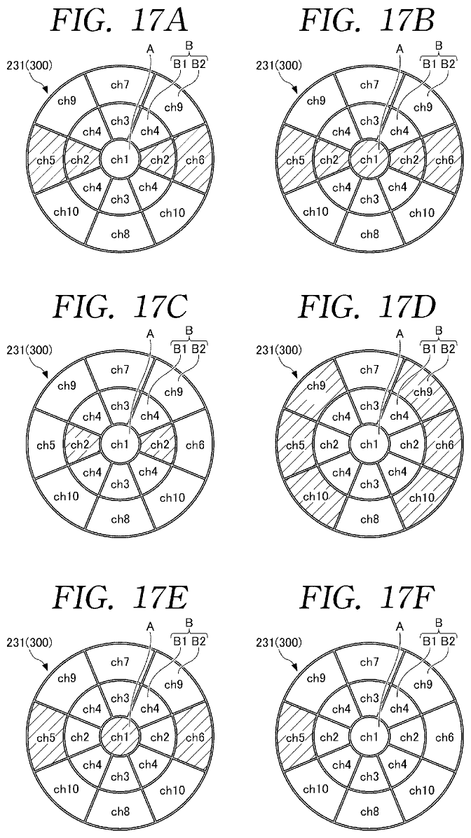

Furthermore, in the above-described exemplary embodiment, the zones of the lower chuck 231 when attracting the lower wafer W2 are the zones ch5 and ch6 on the X-axis and the zones ch7 and ch8 on the Y-axis. However, the bonding apparatus 1 may arbitrarily set the zones when the lower wafer W2 is to be attracted. For example, FIG. 17A to FIG. 17F show various examples of the zones of the lower chuck 231 when attracting the lower wafer W2.

The bonding apparatus 1 according to a first modification example shown in FIG. 17A further uses the zone ch2 of the first outer region B1 in addition to the zones ch5 and ch6 of the second outer region B2 when attracting the X-axis of the lower wafer W2. In this case as well, the lower chuck 231 can transform the attraction surface 300 in the state that the X-axis of the lower wafer W2 is well fixed. Further, when attracting the Y-axis of the lower wafer W2, the bonding apparatus 1 may apply the attracting pressure to the zones ch3, ch7, and ch8.

The bonding apparatus 1 according to a second modification example shown in FIG. 17B further uses the zone ch1, which is the central region A, in addition to the zones ch2, ch5, and ch6, which belong to the outer region B, when attracting the X-axis of the lower wafer W2. In this case as well, the lower chuck 231 can transform the attraction surface 300 in the state that the X-axis of the lower wafer W2 is well fixed. Further, when attracting the Y-axis of the lower wafer W2, the bonding apparatus 1 may apply the attracting pressure to the zones ch1, ch3, ch7, and ch8.

The bonding apparatus 1 according to a third modification example shown in FIG. 17C generates the attracting pressure only in the zone ch2 of the first outer region B1 when attracting the X-axis of the lower wafer W2. As a result, when it is required to stretch a midway portion between the center and the outer edge of the lower wafer W2, for example, that portion can be fixed and transformed. Further, when attracting the Y-axis of the lower wafer W2, the bonding apparatus 1 may apply the attracting pressure to the zone ch3.

The bonding apparatus 1 according to a fourth modification example shown in FIG. 17D generates the attracting pressure in the zones ch9 and ch10, which are the zones in the diagonal directions, in addition to the zones ch5 and ch6 of the second outer region B2 when attracting the X-axis of the lower wafer W2. As a result, a wide area of the outer edge of the lower wafer W2, for example, can be attracted to the lower chuck 231, making it possible to expand the range in the circumferential direction in which the lower wafer W2 is stretched. Additionally, when attracting the Y-axis of the lower wafer W2, the bonding apparatus 1 may apply the attracting pressure to the zones ch7 to ch10.

The bonding apparatus 1 according to a fifth modification example shown in FIG. 17E further uses the zone ch1 of the central region A in addition to the zones ch5 and ch6 of the second outer region B2 when attracting the X-axis of the lower wafer W2. In this case as well, the lower chuck 231 can transform the attraction surface 300 in the state that the X-axis of the lower wafer W2 is well fixed. Further, when attracting the Y-axis of the lower wafer W2, the bonding apparatus 1 may apply the attracting pressure to the zones ch1, ch7, and ch8.

The bonding apparatus 1 according to a sixth modification example shown in FIG. 17F does not attract both ends of the X-axis of the lower wafer W2 but attracts only one end thereof (zone ch5 in FIG. 17F). For example, when it is required to stretch a portion of the lower wafer W2, that portion can be successfully stretched by attracting the lower wafer W2 through a channel corresponding thereto. Further, when attracting the Y-axis of the lower wafer W2, the bonding apparatus 1 may apply the attracting pressure to the zone ch7 or the zone ch8. In short, the zones that attract the lower wafer W2 do not necessarily have to be symmetrically arranged.

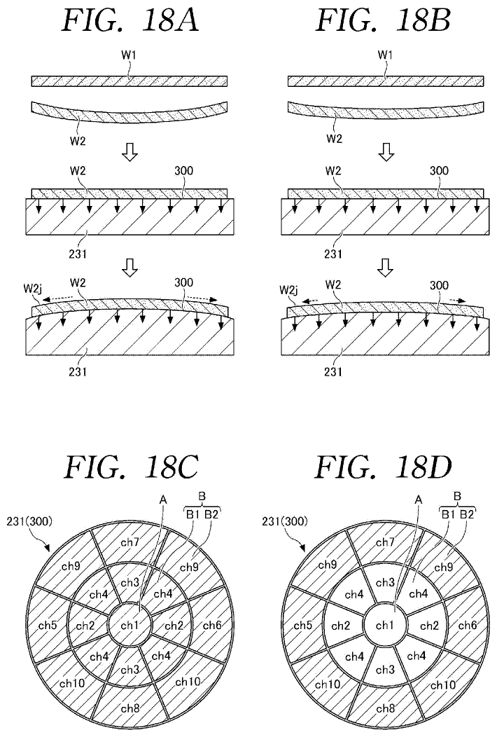

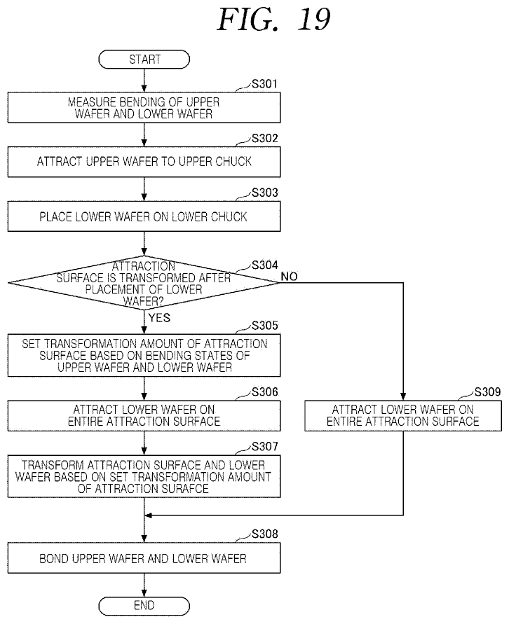

Now, a substrate placing method of the substrate processing apparatus (bonding apparatus 1) according to another exemplary embodiment will be described with reference to FIG. 18A to FIG. 19. In the substrate placing method according to another exemplary embodiment, the attraction surface 300 is transformed after placing the lower wafer W2 on the lower chuck 231 and attracting the lower wafer W2 by generating the attracting pressure in all of the zones of the attraction surface 300, which is different from the above-described substrate placing method in which the attraction is performed for each zone individually. Furthermore, in this substrate placing method, a transformation amount (protrusion amount or recessed amount of the attraction surface 300) of the attraction surface 300 is adjusted based on the bending states (differences between the bending amounts in the respective bending directions) of the upper wafer W1 and the lower wafer W2.

Here, in a conventional bonding apparatus, a lower chuck is transformed before the lower wafer W2 is placed, and the lower wafer W2 is placed on the transformed lower chuck. In this case, a transformation amount (extension or contraction: movement of a reference point) of the lower wafer W2 with respect to the transformation of the lower chuck decreases. In contrast, in the substrate placing method according to another exemplary embodiment, the lower wafer W2 is placed while maintaining its flat surface that it has before being placed, and after being placed, the attraction surface 300 is transformed by attracting the entire lower wafer W2. As a result, the lower wafer W2 is transformed integrally with the lower chuck 231, so that the transformation amount increases. For example, even when the transformation amount of the lower wafer W2 increases due to a large deviation between the respective reference points of the upper wafer W1 and the respective reference point of the lower wafer W2, the lower chuck 231 can still transform the lower wafer W2 in a wide range thereof.

As depicted in FIG. 18A, the control device 90 increases the transformation amount of the attraction surface 300 as the difference in the bending amount between the upper wafer W1 and the lower wafer W2 increases. To the contrary, as shown in FIG. 18B, the control device 90 decreases the transformation of the attraction surface 300 as the difference in the bending amount between the upper wafer W1 and the lower wafer W2 decreases. As a result, the lower chuck 231 can move the respective reference points of the lower wafer W2 to appropriate positions, following the transformation of the attraction surface 300. Further, when transforming a wafer in a substrate processing apparatus other than the bonding apparatus 1, the transformation amount of the attraction surface may be set based on a bending amount of the wafer to be placed rather than the difference between two wafers.

In addition, the bonding apparatus 1 is capable of transforming the entire lower wafer W2 stably by attracting the lower wafer W2 from all the zones of the attraction surface 300 of the lower chuck 231 as shown in FIG. 18C. In this case as well, the attracting pressure generator 310 may generate the attracting pressure in at least some of the plurality of zones in the outer region B (see FIG. 11). However, the bonding apparatus 1 is not limited to being configured to attract the entire lower wafer W2. For example, as shown in FIG. 18D, the lower wafer W2 may be attracted by all the zones ch5 to ch10 of the second outer region B2 that are arranged along the circumferential direction or by all the zones of the outer region B. By fixing an outer peripheral portion of the lower wafer W2 in an annular shape, it becomes possible to intensively stretch the outer peripheral portion of the lower wafer W2, which is largely transformed, following the transformation of the attraction surface 300.

Hereinafter, the substrate placing method according to the another exemplary embodiment will be described with reference to a flowchart of FIG. 19. The control device 90 controls the individual components of the bonding apparatus 1 to carry out processes S301 to S308 in FIG. 19. The processes S301 to S303 are substantially the same as the processes S201 to S203 in FIG. 16, so detailed description thereof will be omitted here.

In the process S304, the control device 90 determines whether or not to transform the attraction surface 300 based on the measured bending states of the upper wafer W1 and the lower wafer W2. For example, when the respective reference points of the upper wafer W1 and the respective reference points of the lower wafer W2 are roughly aligned in advance, the control device 90 makes a decision not to transform the attraction surface 300 (process S304: NO), and proceeds to the process S309. That is, depending on the bending state of the upper wafer W1 and the lower wafer W2, the control device 90 chooses to attract the attraction surface 300 as it is without transforming it. Meanwhile, when the reference points of the upper wafer W1 and the reference points of the lower wafer W2 are deviated from each other, the control device 90 makes a decision to transform the attraction surface 300 (process S304: YES), and proceeds to the process S305.

In the process S305, the control device 90 sets the transformation amount of the attraction surface 300 based on the acquired bending states of the upper wafer W1 and the lower wafer W2. The control device 90 calculates the transformation amount enabling the respective reference points of the upper wafer W1 and the respective reference points of the lower wafer W2 to be aligned by using calculation formulas, map information, etc., that are acquired in advance, and the bending states (differences between the bending amounts in the respective bending directions) of the upper wafer W1 and the lower wafer W2.

Then, after the lower wafer W2 is placed on the attraction surface 300, the control device 90 operates the attracting pressure generator 310 to attract the lower wafer W2 on the entire attraction surface 300 (process S306). As a result, the entire non-bonding surface W2n of the lower wafer W2 is fixed to the attraction surface 300.

Next, the control device 90 transforms the attraction surface 300 and the lower wafer W2 based on the transformation amount of the attraction surface 300 calculated in the process S305 (process S307). The lower wafer W2 fixed to the entire attraction surface 300 is smoothly transformed, following the transformation of the attraction surface 300. By way of example, even when there is a large deviation between the respective reference points of the upper wafer W1 and the respective reference points of the lower wafer W2, the respective reference points of the lower wafer W2 can be moved according to the transformation of the attraction surface 300 so as to eliminate the positional deviation between the respective reference points.

Additionally, when it is determined in the process S304 that the attraction surface 300 is not to be transformed, the control device 90 attracts the lower wafer W2 on the entire attraction surface 300 in the process S309. As a result, the lower wafer W2 can be fixed to the attraction surface 300 that is not transformed.

Finally, the control device 90 performs a bonding operation to bond the upper wafer W1 and the lower wafer W2 while holding the lower wafer W2 by the lower chuck 231 (process S308: process C). By performing the processing sequence of processes S305 to S307, or process S309, the bonding apparatus 1 is capable of bonding the upper wafer W1 and the lower wafer W2 with high precision while allowing the reference points of the upper wafer W1 and the reference points of the lower wafer W2 to be aligned with each other.

After the upper wafer W1 and the lower wafer W2 are bonded, the bonding apparatus 1 releases the attraction of the bonded wafer T. For example, while maintaining the transformed attraction surface 300, the bonding apparatus 1 releases the attraction of the lower wafer W2 when the lift pins 265 are raised to collect the bonded wafer T, thus allowing the bonded wafer T to be transferrable. Accordingly, the bonded wafer T can be transferred faster as compared to a case when it is transferred after reversing the transformation of the attraction surface 300, so that a throughput can be improved. In addition, the timing for releasing the attraction of the bonded wafer T and the timing for releasing the transformation of the attraction surface 300 are not particularly limited, and may be set as required.

As described above, in the substrate placing method according to the another exemplary embodiment as well, a distribution of the stress of the lower wafer W2 can be improved, and the lower wafer W2 can be properly maintained. In particular, in this substrate placing method, the attraction surface 300 is transformed in a transformation amount that is based on the bending states of the upper wafer W1 and the lower wafer W2. Accordingly, the reference points of the upper wafer W1 and the reference points of the lower wafer W2 can be easily aligned. Besides, as the lower wafer W2 is expanded or contracted due to the transformation of the attraction surface 300 in the state that it is attracted to the lower chuck 231, the transformation amount of the lower wafer W2 increases. Therefore, even when the deviation between the reference points of the upper wafer W1 and the reference points of the lower wafer W2 is large, it is possible to sufficiently transform the lower wafer W2 to align the reference points.

Moreover, this substrate placing method may also take various modification examples. For example, in the above description, after the lower wafer W2 is placed on the lower chuck 231 in the state that the attraction surface 300 is kept flat, the attraction surface 300 is deformed. However, without being limited thereto, the bonding apparatus 1 may have a configuration in which the lower wafer W2 is placed on the attraction surface 300 of the lower chuck 231 that is slightly transformed, and after this placement, the attraction surface 300 is further transformed. As an example, in the bonding apparatus 1, the lower wafer W2 may be placed in the state that the attraction surface 300 of the lower chuck 231 is transformed by 50 μm in advance, and the attraction surface 300 may be further transformed by 50 μm (a total of 100 μm) after the lower wafer W2 is placed. In addition, the bonding apparatus 1 may make a decision not to transform the attraction surface 300 after the lower wafer W2 is placed in the state that the attraction surface 300 is transformed previously.

Moreover, in the substrate placing method, the lower wafer W2 may be attracted by some of the zones of the lower chuck 231, and the transformation of the lower wafer W2 may be performed while adjusting the transformation amount of the attraction surface 300 in this attracted state. Thus, according to the substrate placing method, even when deviation amounts of the reference points in the X-axis direction and the reference points in the Y-axis direction are different, the lower wafer W2 can be transformed such that the reference points in both directions are uniformly arranged.

It should be noted that the substrate processing apparatus (bonding apparatus 1) and the substrate placing method according to the above-described exemplary embodiments are illustrative in all aspects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

According to the exemplary embodiment, it is possible to improve the stress distribution of the substrate to appropriately hold the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus equipped with a holder having, on an attraction surface configured to attract a substrate, a circular central region and an annular outer region disposed outside the central region, the substrate processing apparatus comprising:
an attracting pressure generator configured to generate an attracting pressure in the central region and each of multiple zones separated along a circumferential direction of the outer region individually;
a transforming device configured to transform the central region relative to an outer edge of the holder; and
a controller configured to control the attracting pressure generator and the transforming device,
wherein the controller controls:
attracting the substrate to the attraction surface by operating the attracting pressure generator based on a bending state of the substrate to generate the attracting pressure in at least some of the multiple zones of the outer region; and
transforming, after the attracting of the substrate, the attraction surface by operating the transforming device while carrying on the attracting of the substrate.

2. The substrate processing apparatus of claim 1,
wherein based on a bending amount of the substrate on a first axis and a bending amount of the substrate on a second axis orthogonal to the first axis, the controller generates the attracting pressure in either one of the zone corresponding to the first axis or the zone corresponding to the second axis among the multiple zones of the outer region.

3. The substrate processing apparatus of claim 2,
wherein when the substrate is concavely bent such that an outer edge of the substrate is farther from the attraction surface than a center thereof is in a state that the substrate is placed on the holder and before the substrate is attracted to the attraction surface, the controller generates the attracting pressure in the zone corresponding to either the first axis or the second axis, whichever has a larger bending amount.

4. The substrate processing apparatus of claim 2,
wherein when the substrate is convexly bent such that an outer edge of the substrate is closer to the attraction surface than a center thereof is in a state that the substrate is placed on the holder and before the substrate is attracted to the attraction surface, the controller generates the attracting pressure in the zone corresponding to either the first axis or the second axis, whichever has a smaller bending amount.

5. The substrate processing apparatus of claim 1,
wherein the controller generates the attracting pressure in the multiple zones of the outer region arranged at symmetrical positions with the central region therebetween.

6. The substrate processing apparatus of claim 1,
wherein the outer region comprises a first outer region outside and adjacent to the central region in a radial direction, and a second outer region outside and adjacent to the first outer region in the radial direction, and
the controller generates the attracting pressure in some of the multiple zones of the second outer region.

7. The substrate processing apparatus of claim 1, further comprising:
a measurer configured to measure the bending state of the substrate,
wherein the controller selects, based on the bending state of the substrate measured by the measurer, some of the multiple zones of the outer region configured to attract the substrate prior to the attracting of the substrate.

8. The substrate processing apparatus of claim 1,
wherein the controller sets, based on the bending state of the substrate, a transformation amount of the attraction surface in the transforming of the attraction surface.

9. The substrate processing apparatus of claim 8,
wherein the controller generates the attracting pressure in the entire zones arranged along the circumferential direction among the multiple zones of the outer region in the attracting of the substrate, thus allowing the substrate to be attracted to the attraction surface.

10. The substrate processing apparatus of claim 9,
wherein the controller generates the attracting pressure in the central region and all of the multiple zones of the outer region in the attracting of the substrate, thus allowing the substrate to be attracted to the attraction surface.

11. The substrate processing apparatus of claim 1, further comprising:
an upper holder disposed vertically above the holder, and configured to hold a first substrate,
wherein a second substrate as the substrate is held by the holder, and
the controller performs bonding the first substrate and the second substrate after the transforming of the attraction surface.

12. The substrate processing apparatus of claim 11,
wherein the controller generates, based on a bending state of the first substrate, the attracting pressure in some of the multiple zones of the outer region in the attracting of the substrate.

13. The substrate processing apparatus of claim 11,
wherein the controller releases attraction of the second substrate while maintaining transformation of the attraction surface after the bonding of the first substrate and the second substrate, thus allowing the first substrate and the second substrate that are bonded to be transferred.

14. The substrate processing apparatus of claim 1,
wherein the controller makes a determination upon whether or not to transform the attraction surface based on the bending state of the substrate prior to the attracting of the substrate and the transforming of the attraction surface.

15. A substrate placing method of a substrate processing apparatus equipped with a holder having, on an attraction surface configured to attract a substrate, a circular central region and an annular outer region disposed outside the central region, the substrate placing method comprising:
attracting the substrate to the attraction surface by operating, based on a bending amount of the substrate, an attracting pressure generator configured to generate an attracting pressure in the central region and each of multiple zones separated along a circumferential direction of the outer region individually to thereby generate the attracting pressure in at least some of the multiple zones of the outer region; and
after the attracting of the substrate, transforming the attraction surface by operating a transforming device configured to transform the central region relative to an outer edge of the holder while carrying on the attracting of the substrate.
